(19) United States
(12) Patent Application Publication
(10) Pub. No.: US 2017/0069502 A1
(43) Pub. Date: Mar. 9, 2017

(54) MANUFACTURING METHOD OF CARRIER FOR DOUBLE-SIDE POLISHING APPARATUS, CARRIER FOR DOUBLE-SIDE POLISHING APPARATUS, AND DOUBLE-SIDE POLISHING METHOD

(71) Applicant: SHIN-ETSU HANDOTAI CO., LTD., Tokyo (JP)

(72) Inventors: Kazuya SATO, Nasushiobara (JP); Yuki TANAKA, Nishigo-mura (JP); Syuichi KOBAYASHI, Shirakawa (JP)

(73) Assignee: SHIN-ETSU HANDOTAI CO., LTD., Tokyo (JP)

(21) Appl. No.: 15/122,520

(22) PCT Filed: Feb. 13, 2015
(86) PCT No.: PCT/JP2015/000662

§ 371 Date: Aug. 30, 2016

(30) Foreign Application Priority Data
Mar. 14, 2014 (JP) 2014-051332

(51) Int. Cl. H01L 21/304; H01L 21/67; H01L 21/683; B24B 37/20; B24B 37/28

(52) U.S. Cl. CPC H01L 21/304; B24B 37/20; B24B 37/28; H01L 21/6835; H01L 21/67092

(57) ABSTRACT

A manufacturing method of a carrier for a double-side polishing apparatus by performing a lapping process on the carrier for a double-side polishing apparatus, being gear shaped and having a holding hole to hold a semiconductor wafer; including: providing an outer carrier, being larger than the carrier for a double-side polishing apparatus in size, having a hole to hold the carrier for a double-side polishing apparatus, and being configured to arrange the center of the hole to be eccentric to the center of the outer carrier; holding the carrier for a double-side polishing apparatus by the outer carrier, with the carrier for a double-side polishing apparatus being put in the hole; and performing a lapping process on the carrier for a double-side polishing apparatus with the center of the hole being eccentric to the center of the outer carrier.

### TECHNICAL FIELD

The present invention relates to a manufacturing method of a carrier for a double-side polishing apparatus, a carrier for a double-side polishing apparatus, and a double-side polishing method.

### BACKGROUND ART

In a double-side polishing apparatus to flatten a semiconductor wafer such as a silicon wafer, it is general to use a disk-like carrier for a double-side polishing apparatus provided with a holding hole to hold the semiconductor wafer (see Patent Document 1).

In a manufacturing process of this carrier for a double-side polishing apparatus, although it is natural to suppress the thickness variation in each carrier within a lot, uniformity of the thickness variation in one piece, i.e. flatness is an important factor for double-side polishing in order to highly flatten a semiconductor wafer by using this carrier for a double-side polishing apparatus.

Accordingly, in a process for manufacturing a carrier for a double-side polishing apparatus, lapping process is performed in order to suppress the thickness variation within a lot (see Patent Document 2). Regarding the carrier for a double-side polishing apparatus applied this lapping process, the thicknesses of the carrier bodies (main part of carrier), which are viewed in the average values, have a variation of 2 μm or so within a lot.

### CITATION LIST

### Patent Literature

Patent Document 1: Japanese Unexamined Patent publication (Kokai) No. 2001-30161
Patent Document 2: Japanese Unexamined Patent publication (Kokai) No. 2009-135424

### SUMMARY OF INVENTION

### Technical Problem

When the thicknesses of one piece of carrier body are viewed on the ranges (difference between maximum and minimum) of all the data not the average values, however, it has revealed that the range is large being 3 μm or more, and a characteristic thickness distribution is exhibited. This characteristic distribution is a distribution in which the central portion of a carrier body (when the center of a carrier body is contained in a work hole to put a work therein, the central portion means the portion nearest to the periphery of the work hole) is thicker than the other portions.

When such a thickness variation is formed in a carrier body, a thickness variation is also formed on the internal circumference of the work hole. To follow this thickness variation, there arises a problem forming a thickness distribution on the insert (the insert is a carrier member made from resin which is put into the internal circumference of the work hole in order to protect the edge portion of a semiconductor wafer).

The thickness of an insert have to be uniform in the circumference direction of the work hole in order to highly flatten a semiconductor wafer, but the thickness of an insert lacks the uniformity due to the thickness distribution of the carrier body, thereby causing degradation of flatness of a semiconductor wafer. Nevertheless, it has not been developed a technology to cope with the thickness distribution of a carrier body, particularly such a distribution that the central portion of a carrier body gets thicker than the other portions.

The present invention was accomplished in view of the above-described problems. It is an object of the present invention to provide a manufacturing method of a carrier for a double-side polishing apparatus which can improve the variation of a thickness distribution caused in lapping of a carrier for a double-side polishing apparatus as well as a carrier for a double-side polishing apparatus, and a double-side polishing method by use of this carrier for a double-side polishing apparatus.

### Solution to Problem

To achieve the foregoing object, the present invention provides a manufacturing method of a carrier for a double-side polishing apparatus by performing a lapping process on the carrier for a double-side polishing apparatus by revolving and rotating thereof, with the carrier for a double-side polishing apparatus being sandwiched between upper and lower turn tables of a lapping apparatus, the carrier for a double-side polishing apparatus being gear shaped and having a holding hole configured to hold a semiconductor wafer; comprising:

providing an outer carrier, the outer carrier being gear shaped and larger than the carrier for a double-side polishing apparatus in size, having a hole configured to hold the carrier for a double-side polishing apparatus, and being configured to arrange the center of the hole to be eccentric to the center of the outer carrier;

holding the carrier for a double-side polishing apparatus by the outer carrier, with the carrier for a double-side polishing apparatus being put in the hole; and

performing a lapping process on the carrier for a double-side polishing apparatus by rotating and revolving the outer carrier and the carrier for a double-side polishing apparatus with the center of the hole being eccentric to the center of the outer carrier, while the held carrier for a double-side polishing apparatus is sandwiched between the upper and lower turn tables of the lapping apparatus.

Such a method makes it possible to suppress a thickness distribution caused in the conventional lapping process, particularly an occurrence of a distribution in which the central portion of a carrier body gets thicker than the other portions, and to manufacture a carrier for a double-side polishing apparatus with the thickness distribution is suppressed.

In this case, it is preferred that the hole has a circular shape, and an eccentricity of the center of the hole to the center of the outer carrier is set to ⅕ or more relative to the diameter of the hole.

This makes it possible to manufacture a carrier for a double-side polishing apparatus in which the thickness variation is more suppressed, particularly the thickness range is suppressed to 2 μm or less.

In this case, it is also possible to set the hole to have a circular shape, and set the diameter of the hole to be larger by 0.5 mm to 1.0 mm compared to the tip diameter of the carrier for a double-side polishing apparatus.

This makes it possible to securely manufacture a carrier for a double-side polishing apparatus with small thickness variation, because in lapping a carrier for a double-side polishing, the rotation of the carrier for a double-side polishing apparatus in a hole is not hampered by the outer carrier.

In this case, it is preferred that the tip diameter of the outer carrier is set to 1.5 times or more relative to the tip diameter of the carrier for a double-side polishing apparatus.

This makes it possible to manufacture a carrier for a double-side polishing apparatus in which the thickness variation is more suppressed, particularly the thickness range is suppressed to 2 μm or less.

The outer carrier can be mode from material selected from carbon tool steel, stainless steel, and titanium.

As the material for the outer carrier, these materials are suitable.

The carrier for a double-side polishing apparatus can be mode from material selected from stainless steel and titanium.

As the material for the carrier for a double-side polishing apparatus, these materials are suitable.

In order to achieve the foregoing object, the present invention provides a carrier for a double-side polishing apparatus manufactured by the foregoing manufacturing method.

Such a carrier for a double-side polishing apparatus has a thickness distribution with small variation, for example, the thickness range is 2 μm or less, and accordingly it can be a carrier for a double-side polishing apparatus which can manufacture a highly flat semiconductor wafer.

In order to achieve the foregoing object, the present invention also provides a double-side polishing method of a semiconductor wafer, wherein: while holding the semiconductor wafer by use of the foregoing carrier for a double-side polishing apparatus in a double-side polishing apparatus, the upper and lower surfaces of the held semiconductor wafer are brought into sliding contact with the upper and lower turn tables each having a polishing pad attached thereto, thereby subjecting the semiconductor wafer to double-side polishing.

Such a double-side polishing method by using a carrier for a double-side polishing apparatus having a thickness distribution with a small variation can manufacture a highly flat semiconductor wafer.

### Advantageous Effects of Invention

The present invention can manufacture a carrier for a double-side polishing apparatus having a thickness distribution with a small variation. The double-side polishing by use of this carrier for a double-side polishing apparatus can give a semiconductor wafer with higher flatness compared to previous methods.

### BRIEF DESCRIPTION OF DRAWINGS

FIG. 1 illustrates a schematic diagram to show an example of a lapping apparatus used for the manufacturing method of a carrier for a double-side polishing apparatus of the present invention;

FIG. 2 illustrates a top view to show an example of a lower turn table of a lapping apparatus used for the manufacturing method of a carrier for a double-side polishing apparatus of the present invention;

FIG. 3 illustrates a schematic diagram to show an example of an outer carrier used for the manufacturing method of a carrier for a double-side polishing apparatus of the present invention;

FIG. 4 illustrates graphs to show flatness distributions of carriers for a double-side polishing apparatus after lapping in Examples and Comparative Example;

FIG. 5 illustrates a schematic diagram to show a lapping apparatus used in Comparative Example;

FIG. 6(a) illustrates a schematic diagram to show an example of a 20B size carrier for a double-side polishing apparatus, (b) illustrates a graph to show distances from periphery points of the work hole to the center;

FIG. 7 illustrates a graph to show a fitting equation of eccentricity X and thickness displacement Y.

### DESCRIPTION OF EMBODIMENTS

Regarding the present invention, the embodiments will be described in the following, but the present invention is not limited thereto.

As described above, in a previous lapping process of a carrier for a double-side polishing apparatus, the central portion of a carrier body becomes thick. When a thickness distribution of the carrier body variates as described above, the thicknesses of an insert, which are put into thereto in a post-step, causes a variation. In double-side polishing of a semiconductor wafer by use of such a carrier for a double-side polishing apparatus in which the thicknesses of the insert or the carrier body are not uniform, there arises a problem of degrading the flatness of the semiconductor wafer.

Accordingly, the inventors have investigated the reason of the foregoing thickness variation caused in a lapping process of a carrier for a double-side polishing apparatus.

As a result, it has found that the distribution having the thicker center portion in a carrier for a double-side polishing apparatus, in which the work hole (a hole to hold a semiconductor wafer) of the carrier for a double-side polishing apparatus is eccentric to the center of the carrier for a double-side polishing apparatus, is caused by the smaller distance from the center of the carrier for a double-side polishing apparatus to the center portion (eccentricity) compared to the other portions in the lapping process.

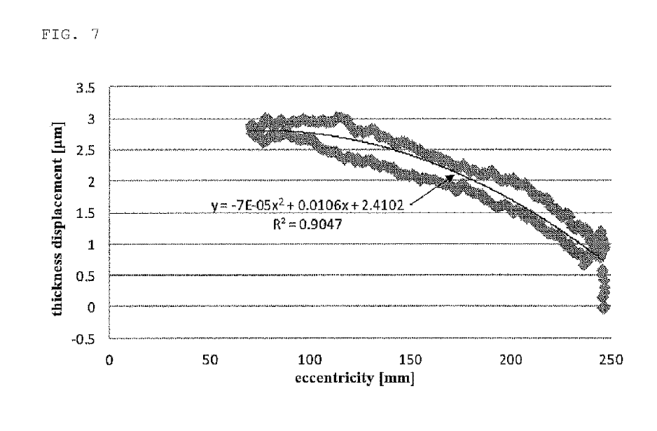

For example, assuming an eccentricity in a standard 20B size (tip diameter: 525 mm) carrier W for a double-side polishing apparatus as shown in FIG. 6(a). The distance of each portion of this carrier W to the center (eccentricity) is about 70 mm at the minimum point, i.e. the central portion (in this case, the portion in the periphery of the work hole 22 nearest to the center), and about 250 mm at the maximum point. Shown in FIG. 6(b) are distances from the periphery points of the work hole 22 to the center.

The correlation between the eccentricity (distance from the center) X and the thickness displacement Y in a carrier for a double-side polishing apparatus in such a size can be represented by the following equation (1) as the result of fitting (curvilinear regression) the measured values as shown in FIG. 7. It is to be noted that the thickness displacement Y are set on the basis of a point at which the eccentricity is the maximum.

Y=−7×10⁻⁵×X²+0.0106X+2.4102 equation (1)

As shown in FIG. 7 and equation (1), the eccentricity and the flatness (thickness distribution) are in inverse correlation. This reveals that it is essential for improving the flatness to ensure the eccentricity at the center portion of a carrier for a double-side polishing apparatus.

On the basis of the foregoing, first, the present inventors have conceived to perform the lapping process by holding a carrier for a double-side polishing apparatus by a holding member, and by rotating and revolving thereof with the holding member unlike the previous arts when performing lapping process on the both sides of the carrier for a double-side polishing apparatus. The present inventors have further conceived that use of a carrier which has a hole to put in the carrier for a double-side polishing apparatus and being configured to arrange the center of the hole to be eccentric to the center of the holding member (hereinafter, this holding member is referred to as an outer carrier) as the foregoing holding member ensures the eccentricity required to uniformize the thickness distribution since the eccentricity of the center of the hole is added to the center of the outer carrier to the eccentricity of the carrier for a double-side polishing apparatus to be lapped; thereby brought the present invention to completion.

The following describes the manufacturing method of a carrier for a double-side polishing apparatus, the carrier for a double-side polishing apparatus, and the double-side polishing method of the present invention.

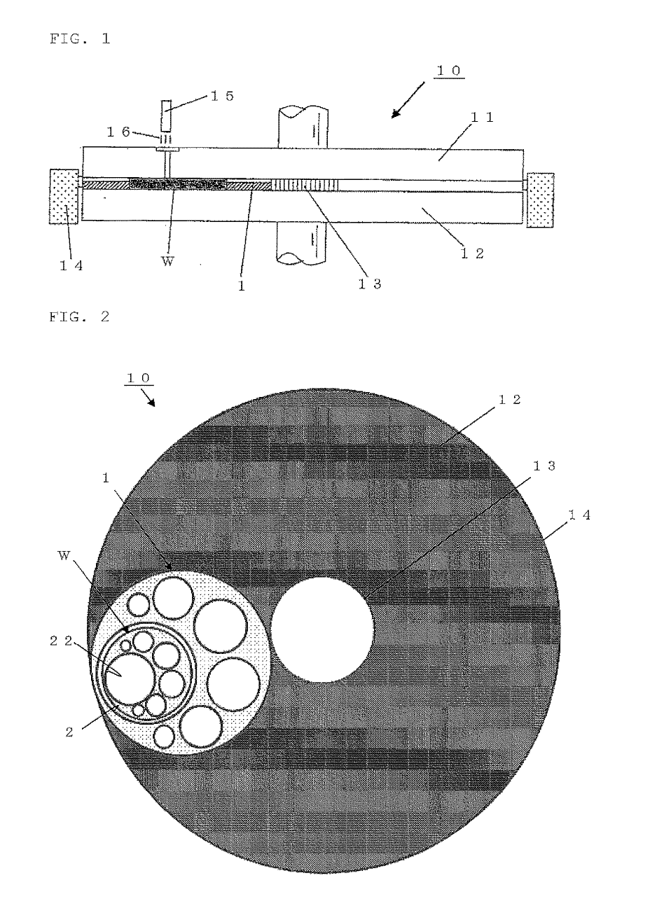

First, the inventive manufacturing method of a carrier for a double-side polishing apparatus is described by citing a case by use of a lapping apparatus shown in FIG. 1. The following describes a case which uses a 20B size (tip diameter: 525 mm) carrier as the carrier for a double-side polishing apparatus to be lapped, and a 32B size (tip diameter: 814 mm) carrier for lapping apparatus as the outer carrier, but the present invention is not limited thereto.

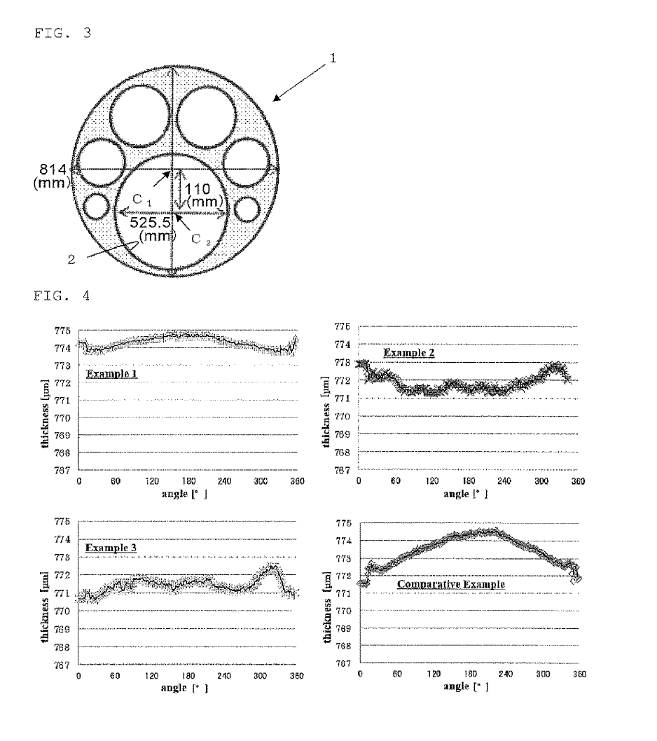

As shown in FIG. 1 and FIG. 2, the lapping apparatus 10 is provided with an upper turn table 11, a lower turn table 12, a sun gear 13, an internal gear 14, and a nozzle 15.

The center part of the lower turn table 12 is provided with the sun gear 13, and the internal gear 14 is located so as to be adjacent to the periphery of the lower turn table 12. From the nozzle 15, slurry 16 is supplied to the space between the upper and lower turn tables 11 and 12 through the hole formed in the upper turn table 11 in the lapping process.

First, such a lapping apparatus 10 is provided with an outer carrier 1 as shown FIG. 1, FIG. 2, and FIG. 3. As this outer carrier 1, the present invention provides and uses the one having a hole 2 configured to hold the carrier W for a double-side polishing apparatus, and being configured to arrange the center C₂ of the hole 2 to be eccentric to the center C₁ of the outer carrier 1 as in FIG. 3.

In this case, material of the outer carrier 1 can be selected from carbon tool steel, stainless steel, and titanium.

These materials have high abrasion-resistance, and is suitable for lapping process thereby.

Then, the outer carrier 1 is engaged to the sun gear 13 and the internal gear 14 in the lapping apparatus 10, and the carrier W for a double-side polishing apparatus is put in the hole 2 of the outer carrier 1 to be held as shown in FIGS. 1 and 2.

In this way, the outer carrier 1 is engaged to the sun gear 13 and the internal gear 14, and by rotating each of these gears, the outer carrier 1 and the carrier W for a double-side polishing apparatus are allowed to perform planetary motion (rotating and revolving motion) around the sun gear 13.

Then, the outer carrier 1 is set in planetary motion by the sun gear 13 and the internal gear 14 while the upper turn table 11 and the lower turn table 12 are rotated in the opposite direction, with the both sides of the carrier W for a double-side polishing apparatus being sandwiched between the upper turn table 11 and the lower turn table 12, and with supplying slurry 16 from the nozzle 15. In this way, the both sides of the carrier W for a double-side polishing apparatus are lapped simultaneously in which the center C₂ of the hole 2 is eccentric to the center C₁ of the outer carrier 1.

By the lapping process to manufacture the carrier W for a double-side polishing apparatus as described above, the eccentricity of the outer carrier 1 is superimposed to the original eccentricity of the carrier for a double-side polishing apparatus, and the eccentricity required to uniformize the thickness distribution is ensured thereby. As a result, it is possible to dissolve the variation of the thickness distribution of the carrier W for a double-side polishing apparatus, and to obtain a carrier for a double-side polishing apparatus with highly uniform thickness.

In this case, it is preferred that the tip diameter of the outer carrier 1 is set to 1.5 times or more relative to the tip diameter of the carrier for a double-side polishing apparatus.

This makes it possible to manufacture a carrier for a double-side polishing apparatus in which the thickness range is suppressed to 2 μm or less.

Moreover, it is preferred that the hole 2 has a circular shape, and an eccentricity of the center of the hole 2 to the center of the outer carrier 1 is set to ⅕ or more relative to the diameter of the hole 2.

This makes it possible to manufacture a carrier for a double-side polishing apparatus in which the thickness range is suppressed to 2 μm or less.

In the following, the reasons for these are described.

In view of uniformity of the flatness, the thickness range of the carrier W for a double-side polishing apparatus is desirable to be 2 μm or less. For example, in a case as in this pattern, using a 20B size (tip diameter: 525 mm) carrier as the carrier for a double-side polishing apparatus to be lapped, and a 32B size (tip diameter: 814 mm) carrier for lapping apparatus as the outer carrier, the eccentricity X required to bring the thickness range to Y≦2 μm is about 180 mm on the basis of the fitting equation (1) and FIG. 7.

For instance, in a common 20B size carrier for a double-side polishing apparatus with an eccentricity to the center of the work hole 22 of 85 to 90 mm as shown in FIG. 6(a), the minimum distance between the center of the carrier for a double-side polishing apparatus to the periphery of the work hole is about 70 mm as shown in FIG. 6(b).

Accordingly, by using an outer carrier 1 in which the center C₂ of the hole 2 is eccentric to the center C₁ of the outer carrier 1 by about 110 mm as shown in FIG. 3, the total eccentricity is brought to about 180 mm, and the thickness range can be 2 μm or less thereby.

This can be fulfilled by using a carrier for a lapping apparatus with the tip diameter of 814 mm (32B size) as the outer carrier as in this example.

The root circle diameter can be 49/50 to the tip diameter, and the root circle diameter in 32B size can be 797.7 mm, although they depend on the pin gear size to engage with the carrier. Accordingly, the eccentricity which can superimpose the outer carrier is calculated as (797.7−525)÷2=136.4 mm, which can sufficiently cover 110 mm.

As described above, in selecting an outer carrier 1, it is possible to refer the difference between the radius of the outer carrier 1 and the radius of the hole 2.

When lapping a 20B size (tip diameter: 525 mm) carrier W for a double-side polishing apparatus as described above, the outer carrier 1 preferably has a size 32B (tip diameter: 814 mm) or more. That is, not only in this case but also in other cases, the eccentricity to bring the thickness range to 2 μm or less can be ensured by setting the tip diameter of the outer carrier 1 to 1.5 times or more relative to the tip diameter of the carrier for a double-side polishing apparatus.

In this case, it is also possible to achieve the thickness range of 2 μm or less by setting the center of the hole 2 eccentric to the center of the carrier by 110 mm or more. That is, not only in this case, it is possible to ensure the eccentricity to fulfill the thickness range of 2 μm or less by setting the eccentricity of the center of the hole 2 to the center of the outer carrier 1 to ⅕ or more relative to the diameter (in this case, about 525.5 mm, which is almost same as the tip diameter of the carrier W for a double-side polishing apparatus) of the hole 2 which holds the carrier W for a double-side polishing apparatus.

In the present invention, it is preferred that the hole 2 has a circular shape, and the diameter of the hole 2 is set to larger by 0.5 mm to 1.0 mm compared to the tip diameter of the carrier W for a double-side polishing apparatus.

When a clearance of 0.5 mm to 1.0 mm is contained between the carrier W for a double-side polishing apparatus to be lapped and the internal circumference of the hole 2 to put in and hold thereof, the carrier W for a double-side polishing apparatus is not disturbed to rotate in the hole 2, and accordingly a carrier for a double-side polishing apparatus with small thickness variation can be securely manufactured.

In the present invention, material of the carrier W for a double-side polishing apparatus can be selected from stainless steel and titanium.

The inventive manufacturing method is suitable to manufacture a carrier W for a double-side polishing apparatus especially made from these materials.

It is to be noted that in the present invention, the lapping condition can be a conventional condition, for example, it is possible to use common materials such as GC#2000 as the slurry 16 to finish to the designated thickness under the designated pressure. It is also possible to manufacture a carrier W for a double-side polishing apparatus as follows: putting a resin insert made from EG (glass-epoxy resin) or aramid into an internal circumference portion of the work hole 22 with pressurizing after performing an above-mentioned lapping process on the carrier W for a double-side polishing apparatus; and performing a finishing polish process to adjust the thickness of a resin.

The foregoing carrier W for a double-side polishing apparatus manufactured by the inventive manufacturing method can be a carrier for a double-side polishing apparatus with little variation of the thickness distribution after the lapping process and having high flatness.

Such a carrier can improve the flatness of a semiconductor wafer when used for double-side polishing of the semiconductor wafer in a double-side polishing apparatus.

The present invention also provides a double-side polishing method of a semiconductor wafer, wherein: while holding the semiconductor wafer by use of the carrier W for a double-side polishing apparatus in a double-side polishing apparatus, the upper and lower surfaces of the held semiconductor wafer are brought into sliding contact with the upper and lower turn tables each having a polishing pad attached thereto, thereby subjecting the semiconductor wafer to double-side polishing.

Such a double-side polishing method by using a carrier for a double-side polishing apparatus with a small thickness variation can manufacture a highly flat semiconductor wafer.

It is to be noted that the forgoing explanation exemplifies a case which uses a 20B size carrier for a double-side polishing apparatus as the object of the lapping process, and a 32B size carrier for lapping apparatus as the outer carrier, but the present invention is not limited thereto. The object of lapping process is not limited to the one with the foregoing size. Regarding the outer carrier, it is not necessary to use the carrier for a lapping apparatus as described above, so long as the center of the hole to hold the object for lapping process is eccentric to the center of the outer carrier.

The forgoing explanation exemplifies a case to lap one piece of carrier W for a double-side polishing apparatus in a lapping apparatus 10 as shown in FIGS. 1 and 2, but it is also possible to perform lapping process on plural pieces of carrier W for a double-side polishing apparatus at the same time, which can efficiently manufacture carriers for a double-side polishing apparatus.

### EXAMPLE

The present invention will be more specifically described below with reference to Example and Comparative Example, but the present invention is not limited thereto.

### Example 1

By use of a lapping apparatus as shown in FIG. 1 and FIG. 2, lapping process was performed on the both sides of a 20B (tip diameter: 525 mm, root circle diameter: 515 mm) size carrier for a double-side polishing apparatus made from titanium.

In this case, a 32B (tip diameter: 814 mm, root circle diameter: 797.7 mm) size carrier for a lapping apparatus made from carbon tool steel was used as an outer carrier. The hole of this outer carrier was set to a circular shape with a diameter of 525.5 mm. In this case, the eccentricity of the center of the hole to the center of the outer carrier was set to 110 mm.

The lapping process was performed until the designated thickness by using GC#2000 as slurry under a constant loading condition.

Table 1 shows the conditions of the carrier for a double-side polishing apparatus to be lapped and the outer carrier in this case.

Then, the flatness distribution was measured on the carrier for a double-side polishing apparatus made from titanium after the lapping process. In the measurement, the flatness distribution on the periphery portion of the work hole was measured by the use of a laser displacement meter manufactured by KEYENCE CORPORATION.

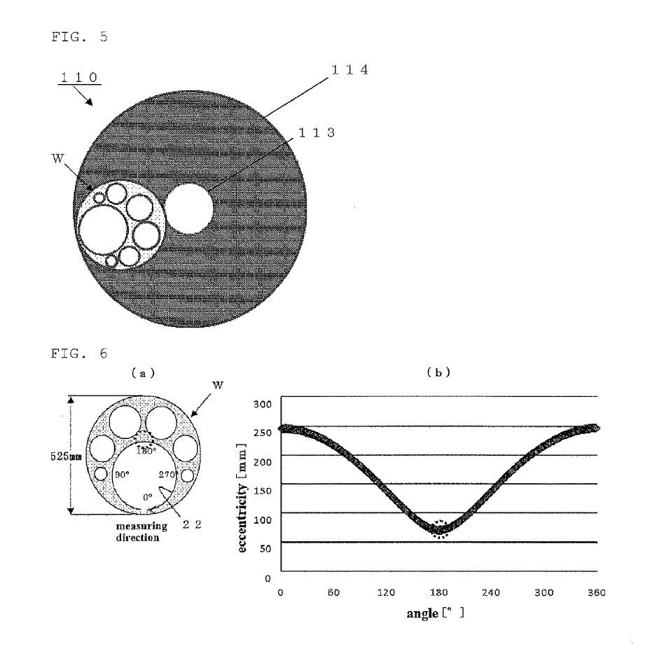

The results are shown in FIG. 4 and Table 2. It is to be noted that the angles on the abscissa in graphs of FIG. 4 represents each angle of measuring point on the periphery portion of the work hole as in FIGS. 6(a) and (b).

As shown in FIG. 4, the flatness distribution after the lapping process was uniform unlike Comparative Example described below, in which the central portion (the vicinity of 180°) got extremely thick compared to the other portions. The thickness range was 1.12 μm and the deviation of the thickness (thickness variation) was 0.30 μm, which were remarkably excellent values compared to Comparative Example.

Then, an insert with an inside diameter of 300.5 mm made from aramid resin was put into the internal circumference of the work hole of the carrier for a double-side polishing apparatus made from titanium after the lapping process. The insert was put in with pressing, and was subjected to finishing polish processing in order to adjust the thickness of the insert to the thickness of the carrier for a double-side polishing apparatus, thereby manufacturing a carrier for a double-side polishing apparatus.

This was used for double-side polishing of semiconductor silicon wafers with a diameter of 300 mm; by using DSP-203 manufactured by Fujikoshi Machinery Corp. as the double-side polishing apparatus, MH-S15A manufactured by Nitta Haas Incorporated as the polishing pad, and GLANZOX2100 manufactured by Fujimi Incorporated as the polishing slurry. In the double-side polishing, the number of wafers to be processed was 5 pieces per 1 batch, and each 10 batches of processing were performed.

Then, the ESFQR (Edge Site Frontsurface referenced least sQuares/Range) was measured as the flatness of a semiconductor silicon wafer after polishing with Wafersight M49mode/1mmEE manufactured by KLA-Tencor Corporation.

Table 3 shows a measured results of the flatness of the semiconductor silicon wafers.

In Example 1, ESFQR max was 31.24 nm and ESFQR sigma (deviation) was 5.07. The ESFQR was improved by 10% in the average values, and the deviation was improved by about 50% compared to Comparative Example, which revealed an improved flatness.

### Example 2

As in the same conditions with Example 1, except that the eccentricity of the center of the hole to the center of the outer carrier was set to 90 mm, 20B size carriers for a double-side polishing apparatus were subjected to lapping process, and the flatness distribution were measured. Table 1 shows the conditions of the carrier for a double-side polishing apparatus to be lapped and the outer carrier in this case.

The measured results of the flatness distribution after lapping process are shown in FIG. 4 and Table 2.

As shown in FIG. 4, the flatness distribution after the lapping process was uniform unlike Comparative Example described below, in which the central portion got extremely thick compared to the other portions. The thickness range was 1.75 μm and the deviation of the thickness (thickness variation) was 0.46 μm, which were excellent values compared to Comparative Example.

Subsequently, an insert was put into the carrier for a double-side polishing apparatus after the lapping as in Example 1. Then, by using this carrier for a double-side polishing apparatus, semiconductor silicon wafers were subjected to double-side polishing process as in Example 1, and the ESFQR of the semiconductor silicon wafers after polishing were measured.

These results are shown in Table 3.

The maximum value of the ESFQR was 33.00 nm, the deviation (variation) was 7.56, which are smaller compared to Comparative Example, and the flatness of the semiconductor wafers were largely improved.

### Example 3

As in the same conditions with Example 1, except that the outer carrier was altered to 30B (tip diameter: 743.8 mm, root circle diameter: 730.8 mm) size carrier for a lapping apparatus, and the eccentricity of the center of the hole to the center of the outer carrier was set to 90 mm, 20B size carriers for a double-side polishing apparatus were subjected to lapping process, and the flatness distribution was measured. Table 1 shows the conditions of the carrier for a double-side polishing apparatus to be lapped and the outer carrier in this case.

The measured results of the flatness distribution after lapping process are shown in FIG. 4 and Table 2.

As shown in FIG. 4, the flatness distribution after the lapping process was uniform unlike Comparative Example described below, in which the central portion got extremely thick compared to the other portions. The thickness range was 1.96 μm and the deviation of the thickness was 0.39 μm, which were excellent values compared to Comparative Example.

Subsequently, an insert was put into the carrier for a double-side polishing apparatus after the lapping as in Example 1. Then, by using this carrier for a double-side polishing apparatus, semiconductor silicon wafers were subjected to double-side polishing process as in Example 1, and the ESFQR of the semiconductor silicon wafers after polishing were measured.

These results are shown in Table 3.

The maximum value of the ESFQR was 33.17 nm, the variation (deviation) was 7.9 nm, which are smaller compared to Comparative Example, and the flatness of the semiconductor wafers were largely improved.

### Comparative Example 1

As in the same conditions with Example 1, except that the carrier W for a double-side polishing apparatus to be lapped were not held by an outer carrier as in FIG. 5 and were directly engaged to the sun gear 113 and the internal gear 114 in a lapping apparatus 110 to be lapped, carriers for a double-side polishing apparatus were subjected to lapping process, and the flatness distribution was measured. Table 1 shows the conditions of the carrier for a double-side polishing apparatus to be lapped and the outer carrier in this case.

The measured results of the flatness distribution after lapping are shown in FIG. 4 and Table 2.

As shown in FIG. 4, the central portions of the carriers for a double-side polishing apparatus got thick in Comparative Example. The thickness range was 3.04 μm and the thickness variation was 0.81 μm, which were largely degraded compared to Examples 1 to 3.

Subsequently, an insert was put into the carrier for a double-side polishing apparatus after the lapping as in Example 1. Then, by using this carrier for a double-side polishing apparatus, semiconductor silicon wafers were subjected to double-side polishing process as in Example 1, and the ESFQR of the semiconductor silicon wafers after polishing were measured.

These results are shown in Table 3.

In Comparative Example, the maximum value of the ESFQR was 40.04 nm, the variation (deviation) was 12.03 nm, and the flatness of the semiconductor wafers were largely degraded compared to Examples 1 to 3.

TABLE 1

| | Carrier for | | | | | Size of | |
|---|---|---|---|---|---|---|---|
| | double-side | | | | | outer | |
| | polishing | | | | | carrier/Size | |
| | apparatus | | Outer carrier | | | of | Eccentricity/ |
| | | Tip | | Tip | | carrier for | Diameter |
| | | diameter | | diameter | Eccentricity | double-side | of |
| | Size | [mm] | Size | [mm] | [mm] | polishing | hole |
| Example 1 | 20B | 525 | 32B | 814 | 110 | 1.55 | 0.21 |
| Example 2 | 20B | 525 | 32B | 814 | 90 | 1.55 | 0.17 |
| Example 3 | 20B | 525 | 30B | 744 | 90 | 1.42 | 0.17 |
| Comparative | 20B | 525 | — | — | — | — | — |
| Example 1 | | | | | | | |

TABLE 2
unit: μm

| | | | | Comparative |
|---|---|---|---|---|
| | Example 1 | Example 2 | Example 3 | Example 1 |
| Maximum | 774.83 | 772.98 | 772.53 | 774.57 |
| Minimum | 773.71 | 771.23 | 770.57 | 771.53 |
| Range | 1.12 | 1.75 | 1.96 | 3.04 |
| Deviation | 0.30 | 0.46 | 0.39 | 0.81 |

TABLE 3
unit: nm

| | | | | Comparative |
|---|---|---|---|---|
| | Example 1 | Example 2 | Example 3 | Example 1 |
| ESFQR max | 31.24 | 33 | 33.17 | 40.04 |
| ESFQR sigma | 5.07 | 7.56 | 7.9 | 12.03 |
| N | 50 | 50 | 50 | 50 |

Table 4 shows a summary of the conditions of Examples and Comparative Example, the measured values of thickness ranges of the carriers for a double-side polishing apparatus after lapping, and the ESFQR of the semiconductor wafers after double-side polishing.

TABLE 4

| | Size of outer | | | | |
|---|---|---|---|---|---|
| | carrier/ | | | | |
| | Size of | | | | |
| | carrier for | Eccentricity/ | Thickness | ESFQR | ESFQR |
| | double-side | Diameter of | range | max | sigma |
| | polishing | hole | [μm] | [nm] | [nm] |
| Example 1 | 1.55 | 0.21 | 1.12 | 31.24 | 5.07 |
| Example 2 | 1.55 | 0.17 | 1.75 | 33 | 7.56 |
| Example 3 | 1.42 | 0.17 | 1.96 | 33.17 | 7.9 |
| Comparative | — | — | 3.04 | 40.04 | 12.03 |
| Example 1 | | | | | |

As described above, the variation and range of the thickness distribution of the carriers for a double-side polishing apparatus were largely improved in Examples 1 to 3, in which the inventive manufacturing method was applied, compared to Comparative Example.

Furthermore, in the double-side polishing by use of the carrier for a double-side polishing apparatus manufactured in Examples 1 to 3, the flatness of the semiconductor wafers were largely improved.

Moreover, Example 1 gave better results compared to Examples 2 and 3, since the eccentricity of the center of the hole to the center of the outer carrier was set to ⅕ (=0.20) or more relative to the diameter of the hole, and the tip diameter of the outer carrier was set to 1.5 times or more relative to the tip diameter of the carrier for a double-side polishing apparatus.

Example 2 gave better results compared to Example 3, since the tip diameter of the outer carrier was set to 1.5 times or more relative to the tip diameter of the carrier for a double-side polishing apparatus, although the eccentricity of the center of the hole to the center of the outer carrier was not set to ⅕ or more relative to the diameter of the hole.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1. A manufacturing method of a carrier for a double-side polishing apparatus by performing a lapping process on the carrier for a double-side polishing apparatus by revolving and rotating thereof, with the carrier for a double-side polishing apparatus being sandwiched between upper and lower turn tables of a lapping apparatus, the carrier for a double-side polishing apparatus being gear shaped and having a holding hole configured to hold a semiconductor wafer; comprising:
providing an outer carrier, the outer carrier being gear shaped and larger than the carrier for a double-side polishing apparatus in size, having a hole configured to hold the carrier for a double-side polishing apparatus, and being configured to arrange the center of the hole to be eccentric to the center of the outer carrier;
holding the carrier for a double-side polishing apparatus by the outer carrier, with the carrier for a double-side polishing apparatus being put in the hole; and
performing a lapping process on the carrier for a double-side polishing apparatus by rotating and revolving the outer carrier and the carrier for a double-side polishing apparatus with the center of the hole being eccentric to the center of the outer carrier, while the held carrier for a double-side polishing apparatus is sandwiched between the upper and lower turn tables of the lapping apparatus.

2. The manufacturing method of a carrier for a double-side polishing apparatus according to claim 1, wherein the hole has a circular shape, and an eccentricity of the center of the hole to the center of the outer carrier is set to ⅕ or more relative to the diameter of the hole.

3. The manufacturing method of a carrier for a double-side polishing apparatus according to claim 1 or claim 2, wherein the hole has a circular shape, and the diameter of the hole is set to larger by 0.5 mm to 1.0 mm compared to the tip diameter of the carrier for a double-side polishing apparatus.

4. The manufacturing method of a carrier for a double-side polishing apparatus according to any one of claims 1 to 3, wherein the tip diameter of the outer carrier is set to 1.5 times or more relative to the tip diameter of the carrier for a double-side polishing apparatus.

5. The manufacturing method of a carrier for a double-side polishing apparatus according to any one of claims 1 to 4, wherein material of the outer carrier is selected from carbon tool steel, stainless steel, and titanium.

6. The manufacturing method of a carrier for a double-side polishing apparatus according to any one of claims 1 to 5, wherein material of the carrier for a double-side polishing apparatus is selected from stainless steel and titanium.

7. A carrier for a double-side polishing apparatus manufactured by the manufacturing method according to any one of claims 1 to 6.

8. A double-side polishing method of a semiconductor wafer, wherein: while holding the semiconductor wafer by use of the carrier for a double-side polishing apparatus according to claim 7 in a double-side polishing apparatus, the upper and lower surfaces of the held semiconductor wafer are brought into sliding contact with the upper and lower turn tables each having a polishing pad attached thereto, thereby subjecting the semiconductor wafer to double-side polishing.

1.-8. (canceled)

9. A manufacturing method of a carrier for a double-side polishing apparatus by performing a lapping process on the carrier for a double-side polishing apparatus by revolving and rotating thereof, with the carrier for a double-side polishing apparatus being sandwiched between upper and lower turn tables of a lapping apparatus, the carrier for a double-side polishing apparatus being gear shaped and having a holding hole configured to hold a semiconductor wafer; comprising:
providing an outer carrier, the outer carrier being gear shaped and larger than the carrier for a double-side polishing apparatus in size, having a hole configured to hold the carrier for a double-side polishing apparatus, and being configured to arrange the center of the hole to be eccentric to the center of the outer carrier;
holding the carrier for a double-side polishing apparatus by the outer carrier, with the carrier for a double-side polishing apparatus being put in the hole; and
performing a lapping process on the carrier for a double-side polishing apparatus by rotating and revolving the outer carrier and the carrier for a double-side polishing apparatus with the center of the hole being eccentric to the center of the outer carrier, while the held carrier for a double-side polishing apparatus is sandwiched between the upper and lower turn tables of the lapping apparatus.

10. The manufacturing method of a carrier for a double-side polishing apparatus according to claim 9, wherein the hole has a circular shape, and an eccentricity of the center of the hole to the center of the outer carrier is set to ⅕ or more relative to the diameter of the hole.

11. The manufacturing method of a carrier for a double-side polishing apparatus according to claim 9, wherein the hole has a circular shape, and the diameter of the hole is set to larger by 0.5 mm to 1.0 mm compared to the tip diameter of the carrier for a double-side polishing apparatus.

12. The manufacturing method of a carrier for a double-side polishing apparatus according to claim 10, wherein the hole has a circular shape, and the diameter of the hole is set to larger by 0.5 mm to 1.0 mm compared to the tip diameter of the carrier for a double-side polishing apparatus.

13. The manufacturing method of a carrier for a double-side polishing apparatus according to claim 9, wherein the tip diameter of the outer carrier is set to 1.5 times or more relative to the tip diameter of the carrier for a double-side polishing apparatus.

14. The manufacturing method of a carrier for a double-side polishing apparatus according to claim 10, wherein the tip diameter of the outer carrier is set to 1.5 times or more relative to the tip diameter of the carrier for a double-side polishing apparatus.

15. The manufacturing method of a carrier for a double-side polishing apparatus according to claim 11, wherein the tip diameter of the outer carrier is set to 1.5 times or more relative to the tip diameter of the carrier for a double-side polishing apparatus.

16. The manufacturing method of a carrier for a double-side polishing apparatus according to claim 12, wherein the tip diameter of the outer carrier is set to 1.5 times or more relative to the tip diameter of the carrier for a double-side polishing apparatus.

17. The manufacturing method of a carrier for a double-side polishing apparatus according to claim 9, wherein material of the outer carrier is selected from carbon tool steel, stainless steel, and titanium.

18. The manufacturing method of a carrier for a double-side polishing apparatus according to claim 16, wherein material of the outer carrier is selected from carbon tool steel, stainless steel, and titanium.

19. The manufacturing method of a carrier for a double-side polishing apparatus according to claim 9, wherein material of the carrier for a double-side polishing apparatus is selected from stainless steel and titanium.

20. The manufacturing method of a carrier for a double-side polishing apparatus according to claim 18, wherein material of the carrier for a double-side polishing apparatus is selected from stainless steel and titanium.

21. A carrier for a double-side polishing apparatus manufactured by the manufacturing method according to claim 9.

22. A double-side polishing method of a semiconductor wafer, wherein:
while holding the semiconductor wafer by use of the carrier for a double-side polishing apparatus according to claim 21 in a double-side polishing apparatus, the upper and lower surfaces of the held semiconductor wafer are brought into sliding contact with the upper and lower turn tables each having a polishing pad attached thereto, thereby subjecting the semiconductor wafer to double-side polishing.
